(19) United States
(12) Patent Application Publication
(10) Pub. No.: US 2001/0014513 A1
(43) Pub. Date: Aug. 16, 2001

(54) STI DIVOT AND SEAM ELIMINATION

(76) Inventor: MAX G. LEVY, ESSEX JUNCTION, VT (US)

Correspondence Address: RICHARD L CATANIA, SCULLY SCOTT MURPHY & PRESSER, 400 GARDEN CITY PLAZA, GARDEN CITY, NY, 11530

(21) Appl. No.: 09/233,888

(22) Filed: Jan. 20, 1999

(51) Int. Cl. H01L 21/76

(52) U.S. Cl. 438/438; 438/436

(57) ABSTRACT

A method for eliminating the divots and seams present in a shallow trench isolation region of a semiconductor device is provided which improves the corner Vt control. The method disclosed herein applies spun-on glass to a surface of a semiconductor device and then anneals the applied spun-on glass prior to stripping the sacrificial oxide layer present on the semiconductor device. The annealing step employed in the present invention densifies the spun-on glass so that its etch rate approximates that of the sacrificial oxide layer.

### FIELD OF THE INVENTION

The present invention relates to semiconductor device manufacturing and in particular to a method for eliminating the shallow trench isolation (STI) divot at the device corner and to fill the STI seams. The elimination of the STI divot at the device corner provides improved corner threshold voltage control making the structures of the present invention suitable for logic and memory applications.

### BACKGROUND OF THE INVENTION

Semiconductor technologies which utilize a corner device such as a 64M dynamic random access memory (DRAM) array require tight control of the corner threshold voltage (Vt). A high Vt in DRAM arrays can result in a signal margin loss due to low device current (Ids), whereas a low Vt in DRAM arrays can result in retention time problems due to sub-Vt leakage.

Ideally, the corner Vt should be equal to the channel Vt of the device. This is difficult to achieve in most semiconductor corner devices since many factors are known to influence the corner Vt. One such factor that may effect the corner Vt is the gate conductor (GC) wrap around at the device corner. The presence of the GC wrap around lowers the Vt below the channel Vt hence causing sub-Vt leakage problems.

No suitable methods, that are easy to implement, are known in the prior art which can substantially control the gate conductor wrap around of such semiconductor devices. There is thus a need for developing a method which is capable of improving the corner Vt control by filling the divots and seams which are present in the STI region of the semiconductor device.

### SUMMARY OF THE INVENTION

One object of the present invention is to provide a method which can be employed in corner semiconductor devices such as DRAM arrays that substantially improves the control of the corner Vt.

Another object of the present invention is to provide a method wherein the shallow trench isolation (STI) divot is eliminated and the STI seams are filled.

A further object of the present invention is to provide a method wherein a spun-on glass is applied to a surface of a semiconductor structure prior to conducting an oxide stripping step thereby eliminating the need for employing any subsequent planarization step.

These and other objects and advantages can be achieved by utilizing the method of the present invention which comprises the following steps:

(a) applying a layer of spun-on glass to a surface of a semiconductor structure, said semiconductor structure having at least one shallow trench isolation (STI) region containing divots and seams therein and a layer of a sacrificial oxide abutting said STI region;

(b) annealing the layer of spun-on glass to densify the spun-on glass such that said layer of spun-on glass has an etch rate that approximates that of the sacrificial oxide layer; and

(c) removing the sacrificial oxide layer and bulk of the annealed layer of spun-on glass so as to provide a planarized structure having densified spun-on glass filling said STI divots and seams.

Another aspect of the present invention relates to a planarized semiconductor structure which is formed using the method of the present invention. It should be noted that prior art semiconductor structures differ from the inventive semiconductor structure since they contain the STI divot and seam therein. In contrast, the semiconductor structure of the present invention does not contain the STI divot or seam; therefore the above mentioned prior art problems have been overcome. Specifically, the semiconductor structure of the present invention comprises a planarized semiconductor substrate or wafer having at least one shallow trench isolation (STI) region, wherein any divots or seams present in said STI region are filled with densified spun-on glass.

### BRIEF DESCRIPTION OF THE DRAWINGS

FIGS. 1(a)-(c) are cross-sectional views illustrating the various processing steps employed in the present invention to fill the STI divots and seams.

### DETAILED DESCRIPTION OF THE INVENTION

The present invention will now be described in detail with reference to the accompanying drawings, wherein like reference numerals are used for describing like and corresponding elements. It should be note that although the drawings of the present invention illustrate only one STI region, the semiconductor structures contemplated herein can have any number of STI regions.

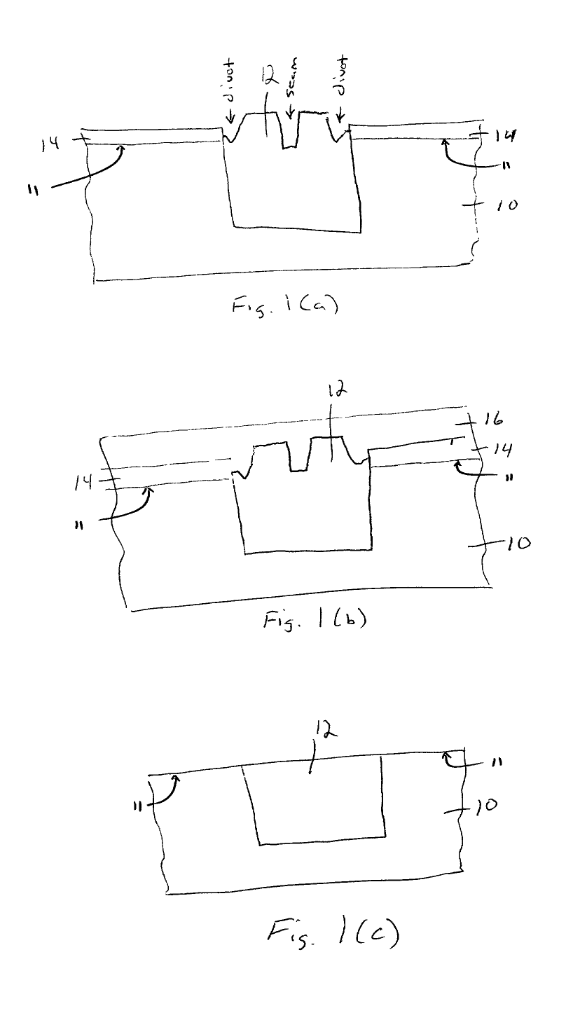

Reference is made to FIG. 1(a) which shows a cross-sectional view of a semiconductor structure that can be employed in the present invention. Specifically, the semiconductor structure shown in FIG. 1(a) comprises a semiconductor substrate or wafer 10, a STI region 12 and a sacrificial oxide layer 14 abutting said STI region 12. STI region 12 contains divots and seams which are formed during the STI manufacturing process.

Semiconductor substrate or wafer 10 is composed of any semiconducting material including, but not limited to: Si, Ge, SiGe, GaAs, InAs, InP and all other III/V compounds. Of these semiconducting material, it is preferred that semiconductor substrate or wafer 10 be composed of Si. The semiconductor substrate or wafer may be of the p-type or the n-type depending on the type of semiconductor device being manufactured.

The structure shown in FIG. 1(a) is fabricated using conventional techniques well known to those skilled in the art. For example, the structure shown in FIG. 1(a) can be fabricated as follows: First, a semiconductor substrate or wafer 10 is provided and a pad oxide layer, e.g. SiO₂, is grown on the surface of semiconductor substrate or wafer 10 using conventional thermal growing techniques which are well known to those skilled in the art. This includes heating the semiconductor substrate or wafer in an oxygen ambient at a temperature of from about 800° to about 1100° C. until an oxide having a thickness of from about 4 to about 10 nm is formed on the surface of the semiconductor substrate or wafer. It is also possible to form pad oxide layer by conventional deposition processes such as, but not limited to: chemical vapor deposition (CVD) and plasma vapor deposition (PVD). It is noted that the pad oxide is not labeled in the drawings since the same is removed in fabricating the structure shown in FIG. 1(a).

A polish stop layer, not shown in the drawings, is then formed on the surface of the pad oxide layer by conventional deposition processes. The polish stop layer is composed of a conventional material such as Si₃N₄ which resists erosion during subsequent planarization and etching.

Next, a STI trench is formed in the polish stop layer and the pad oxide layer as well as the surface of semiconductor substrate or wafer 10. The STI trench is fabricated using standard lithography, etching and planarization, all of which are well known to those skilled in the art.

Specifically, the STI trench is fabricated by providing a conventional resist having a preformed pattern on top of the polish stop layer using standard deposition techniques which include spin-on coating and dip coating. The pattern is then etched by standard etching techniques well known to those skilled in the art through the polish stop layer and pad oxide layer as well as into semiconductor substrate or wafer 10. Suitable etching techniques that can be employed include, but are not limited to: reactive ion etching (RIE), plasma etching and ion beam etching. The depth that etching is performed into the semiconductor substrate or wafer is typically of from about 100 to about 700 nm. It should be noted that the resist is removed at this time using conventional stripping techniques well known to those skilled in the art.

A thermal silicon dioxide layer, not shown in the drawings, is then grown in the trench of the STI region using conventional thermal growing techniques, including the use of an oxygen-containing ambient and heating to a temperature of from about 750° to about 1100° C. The thickness of the grown silicon dioxide layer in the STI trench is typically of from about 3 to about 30 nm. A STI dielectric is then formed over the thermal silicon dioxide layer using standard deposition techniques such as low pressure chemical vapor deposition (LPCVD) or a plasma-assisted process. Suitable STI dielectrics include, but are not limited to: high density plasma tetraethylorthosilicate (HDP TEOS) oxide. It should be noted that in the drawings of the present invention, the thermal silicon dioxide layer is not shown. Instead, STI region 12 is meant to include this layer as well as others that may be present in a conventional STI region.

Standard planarization techniques are used to planarize the STI dielectric down to the polish stop layer. The polish stop layer, along with the underlying pad oxide layer are then removed thus forming STI divots and seams (See, FIG. 1a). Using conventional growing techniques like those mentioned above, a thermal sacrificial oxide layer 14, e.g. SiO₂, is grown on the active surface 11 of substrate 10.

In accordance with the method of the present invention, a conformal layer of spun-on glass 16 is then applied by conventional spinning techniques so as to cover sacrificial oxide layer 14 and STI region 12. This step of the method of the present invention is illustrated in FIG. 1(b). The application of the spun-on glass provides a planarized structure.

Suitable materials that can be employed in forming layer 16 include but are not limited to: silsesquioxanes, flowable oxides and other silicon-containing polymers. Of these materials, it is preferred that a flowable oxide referred to as FOₓ manufactured by Dow Corning or a silsesquioxane be employed in the present invention in forming the layer of spun-on glass. While not being critical to the present invention, the thickness of the applied spun-on glass is typically of from about 100 to about 350 nm.

After the layer of spun-on glass is applied, the structure shown in FIG. 1(b) is then subjected to a melt and flow step. Typically, the melt and flow step is conducted in a nitrogen-containing ambient at 150° C., 200° C. and 350° C. for 1 minute each. Other temperatures and times can also be employed depending on the type of spun-on glass employed in the present invention.

The structure is then subjected to annealing under conditions effective to densify the layer of spun-on glass. Specifically, the annealing conditions employed in the present invention are selected so that the etch rate of the annealed spun-on glass substantially matches that of the underlying sacrificial oxide layer. This selective annealing step is important in the present invention since it ensures that any subsequent etch process will remove the spun-on glass and the sacrificial oxide at similar rates thus preventing the formation of any isotropic divots in the STI region.

In accordance with the present invention, annealing is carried out in an inert gas atmosphere, e.g. nitrogen, argon, helium and the like, which may or may not be mixed with oxygen. When oxygen is employed, from about 5 to about 100% oxygen is employed. A highly preferred gas atmosphere employed in the annealing step of the present invention is 900° C., steam.

The densification of the spun-on glass layer occurs by annealing the structure in an inert gas atmosphere at a temperature of from about 400° to about 1200° C. for a time period of from about 20 to about 120 minutes. More preferably, annealing is conducted at a temperature of from about 850° to about 1000° C. for a time period of from about 45 to about 90 minutes. It should be noted that the annealing step may be carried out in a single ramp step or it can be carried out using a series of ramp and soak cycles.

After annealing and densification of the spun-on glass, the annealed structure is then subjected to a step which is highly selective in removing the bulk of the annealed spun-on glass as well as the sacrificial oxide layer. It is noted that some of the annealed spun-on glass remains after the removal step. Specifically, the present invention employs an oxide etch to remove the sacrificial oxide layer and the annealed spun-on glass layer down to active surface 11 of semiconductor substrate or wafer 10 while leaving annealed spun-on glass in the STI divots and seams. This step of the present invention provides the planarized structure shown in FIG. 1(c).

Suitable oxide etch techniques that can be employed in the present invention include, but are not limited to: dry etching techniques such as reactive ion etching (RIE), plasma etching, ion beam etching and chemical dry etching. The gases which may be employed in these etching techniques are those that have a high affinity and selectivity for the sacrificial oxide layer as well as the annealed spun-on glass layer.

Examples of suitable gases that can be employed in the dry etching process include: CF₄, SF₆ NF₃, CHF₃ and combinations thereof. The gases may also be used in conjunction with oxygen or an inert gas such as nitrogen or helium. Of the above mentioned etching techniques, it is highly preferred in the present invention that RIE be employed to selectively remove the sacrificial oxide layer and bulk of the annealed spun-on glass layer.

Alternatively and more preferably, the oxide etch is carried out using a wet chemical etch process. Suitable chemical etchants which can be employed to selectively remove the densified spun-on glass layer and the sacrificial oxide layer include HF and HNO₃. Buffered solution can also be employed in the present invention. Of these, a 40:1 buffered HF solution is a particularly preferred chemical etchant that can be employed in the present invention.

It is emphasized that the structure shown in FIG. 1(c) is a planarized structure which contains no STI divots or seams in the STI region. Instead, the method of the present invention eliminates the STI divot in the STI region as well as any seams that may be present therein. As such, the present invention permits improved device corner Vt control than heretofore reported using any prior art technique.

While the invention has been particularly shown and described with respect to preferred embodiments thereof, it will be understood by one skilled in the art that the foregoing and other changes can be made without departing from the spirit and scope of the present invention. It is therefore intended that the present invention not be limited to the exact forms described and illustrated, but fall within the scope of the appended claims.

Having thus described my invention in detail, what I claim as new, and desire to secure by the letters Patent is:

1. A method of eliminating divots and seams present in a shallow trench isolation region of a semiconductor structure, said method comprising:
(a) applying a layer of spun-on glass to a surface of a semiconductor structure, said semiconductor structure having at least one shallow trench isolation (STI) region containing divots and seams therein and a layer of a sacrificial oxide abutting said STI region;
(b) annealing the layer of spun-on glass to densify the spun-on glass such that said layer of spun-on glass has an etch rate that approximates that of the sacrificial oxide layer; and
(c) removing the sacrificial oxide layer and bulk of the annealed layer of spun-on glass so as to provide a planarized structure having densified spun-on glass filling said STI divots and seams.

2. The method of claim 1 wherein said semiconductor structure further comprises a semiconductor substrate or wafer.

3. The method of claim 2 wherein said semiconductor substrate or wafer is composed of a semiconducting material selected from the group consisting of Si, Ge, SiGe, GaAs, InAs, InP and other III/V compounds.

4. The method of claim 2 wherein said semiconductor substrate or wafer is composed of Si.

5. The method of claim 1 wherein said spun-on glass is a material selected from the group consisting of silsesquioxane polymers, flowable oxides and other silicon-containing polymers.

6. The method of claim 1 wherein said spun-on glass is composed of a silsesquioxane polymer.

7. The method of claim 1 wherein said annealing step is carried out in an inert gas atmosphere or an inert gas atmosphere mixed with from about 5 to about 100% oxygen.

8. The method of claim 1 wherein said annealing step is carried out in steam.

9. The method of claim 1 wherein said annealing step is carried out at a temperature of from about 400° to about 1200° C. for a time period of from about 20 to about 120 minutes.

10. The method of claim 9 wherein said annealing step is carried out at a temperature of from about 850° to about 1000° C. for a time period of from about 45 to about 90 minutes.

11. The method of claim 1 wherein said removal step is a selective oxide etch process.

12. The method of claim 11 wherein said selective oxide etch process is a dry etch process selected from the group consisting of reactive ion etching, plasma etching, ion beam etching and chemical dry etching.

13. The method of claim 12 wherein the dry etch process employs a gas selected from the group consisting of CF₄, SF₆ NF₃, CHF₃ and combinations thereof.

14. The method of claim 12 wherein said dry etch process is a reactive ion etching process.

15. The method of claim 11 wherein said selective oxide etch process is a wet chemical etch process.

16. The method of claim 15 wherein said wet chemical etch process includes the use of a chemical etchant selected from the group consisting of HF and HNO₃.

17. The method of claim 1 wherein prior to conducting step (b) the spun-on glass is subjected to a melt and flow step.

18. The method of claim 17 wherein said melt and flow step is carried out in a nitrogen-containing atmosphere at 150°, 200° C. and 350° C. for 1 minutes each.

19. A semiconductor structure having corner threshold control comprising a planarized semiconductor substrate or wafer having at least one shallow trench isolation region embedded therein, wherein any divots or seams of said shallow trench isolation region are filled with densified spun-on glass.

20. The semiconductor structure of claim 19 wherein said semiconductor substrate or wafer is composed of a semiconducting material selected from the group consisting of Si, Ge, SiGe, GaAs, InAs, InP and other III/V compounds.

21. The semiconductor structure of claim 20 wherein said semiconductor substrate or wafer is composed of Si.

22. The semiconductor structure of claim 19 wherein said spun-on glass is a material selected from the group consisting of silsesquioxane polymers, flowable oxides and other silicon-containing polymers.

23. The semiconductor structure of claim 22 wherein said spun-on glass is composed of a silsesquioxane polymer.

24. A memory cell array comprising at least the semiconductor structure of claim 19.
